(19) United States
(12) Patent Application Publication
(10) Pub. No.: US 2026/0231338 A1
(43) Pub. Date: Aug. 6, 2026

(54) CIRCUIT BOARD ASSEMBLY WITH EMBEDDED ELECTRONIC DEVICES AND METHOD FOR MANUFACTURING THE SAME

(71) Applicants: HongQiSheng Precision Electronics (QinHuangDao)Co., Ltd., Qinhuangdao (CN); Avary Holding (Shenzhen) Co., Limited., Shenzhen (CN); GARUDA TECHNOLOGY CO., LTD., New Taipei (TW)

(72) Inventors: ZHI-YONG HUANG, Shenzhen (CN); CHIH-CHIEH FU, New Taipei (TW)

(21) Appl. No.: 19/629,094

(22) Filed: Mar. 26, 2026

Related U.S. Application Data
(63) Continuation-in-part of application No. PCT/CN2024/125803, filed on Oct. 18, 2024.

(51) Int. Cl. H05K 1/185; H05K 1/03; H05K 1/09; H05K 3/28; H05K 3/46

(52) U.S. Cl. CPC H05K 1/185; H05K 1/0313; H05K 1/09; H05K 3/28; H05K 3/4697; H05K 2201/10545

(57) ABSTRACT

In the circuit board assembly and the method thereof provided by the embodiments of the present disclosure, the support layer (including the base layer and the adhesive layers) is directly embedded in the through groove of the inner substrate, and the support layer is recessed inside the through groove to form the recess, so that embedded electronic devices can be respectively disposed in the through groove and the recess. The support layer does not need to be peeled off, thereby simplifying the process, improving production efficiency, and avoiding the problem of adhesive layer residue during peeling. In addition, the electronic devices are respectively disposed on upper and lower surfaces of the inner substrate, that is, components can be mounted on both upper and lower sides of the inner substrate, thus improving the space utilization rate of the circuit board assembly.

### FIELD

The subject matter herein generally relates to circuit board technologies, and more particularly, to a circuit board assembly with embedded electronic devices and a method for manufacturing the same.

### BACKGROUND

Conventional embedded carrier materials generally includes a base film, an adhesive layer, and other structures. The carrier material is configured to carry electronic devices so as to embed the electronic devices in a board. After the embedding process is completed, the carrier material is peeled off and separated from the board, and the carrier material is not retained inside the board. However, residual adhesive tends to occur during the peeling process, the process for embedding electronic devices is complicated, and the space utilization rate of the board is low. Therefore, there is a room for improvement in the art.

### BRIEF DESCRIPTION OF THE DRAWINGS

Implementations of the present technology will now be described, by way of example only, with reference to the attached figures.

FIG. 1 is cross-sectional view of an inner substrate manufactured according to one embodiment of the present disclosure.

FIG. 2A is a cross-sectional view of a support layer and a protection layer stacked on one side of the inner substrate shown in FIG. 1.

FIG. 2B is a cross-sectional view of the support layer of the structure shown in FIG. 2A.

FIG. 3 is a cross-sectional view of the support layer and the protection layer shown in FIG. 2A after lamination using a mold.

FIG. 4A is a cross-sectional view of a first electronic device mounted in a through groove of the structure shown in FIG. 3.

FIG. 4B is a cross-sectional view of the structure shown in FIG. 4A after removal of the mold.

FIG. 5 is a cross-sectional view of the structure shown in FIG. 4B after removal of the protection layer.

FIG. 6 is a cross-sectional view of a second electronic device mounted on the structure shown in FIG. 5.

FIG. 7 is a cross-sectional view of adhesive layers disposed on two sides of the structure shown in FIG. 6.

FIG. 8 is a cross-sectional view of a circuit board assembly according an embodiment, obtained by laminating outer substrates on two sides of the structure shown in FIG. 7.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

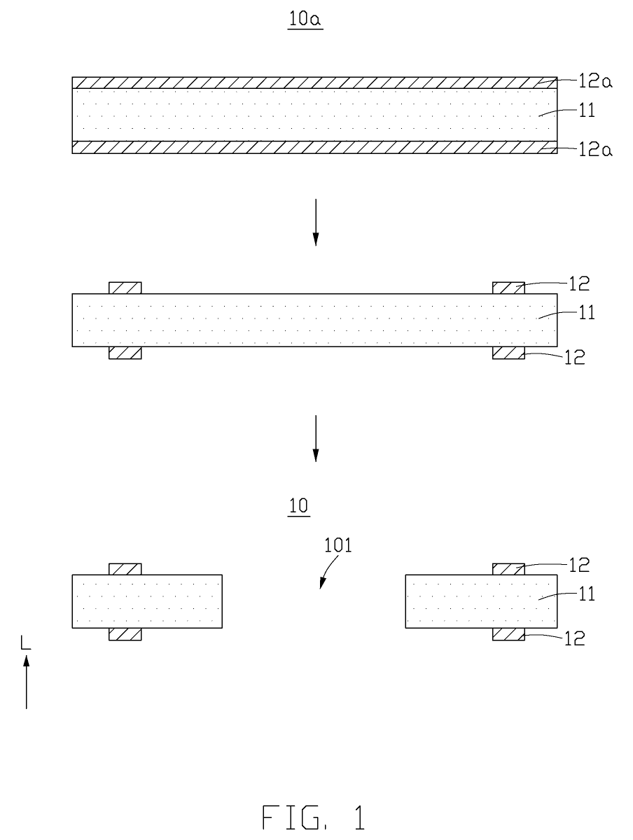

Referring to FIGS. 1 to 8, a method for manufacturing a circuit board assembly 100 is provided according to one embodiment of the present disclosure, which includes steps S10 to S80.

Referring to FIG. 1, in step S10, an inner substrate 10 is provided. The inner substrate 10 defines a through groove 101 extending through the inner substrate 10 along a thickness direction L thereof. The inner substrate 10 is a circuit board formed with conductive circuits, and may be manufactured through steps S11 to S13.

Referring to FIG. 1, in step S11, a copper clad laminate 10a is provided. The copper clad laminate 10a includes a dielectric layer 11 and at least one copper layer 12a disposed on one surface or respective opposing surfaces of the dielectric layer 11. In the embodiment, two copper layers 12a are disposed on two opposite surfaces of the dielectric layer 11 along the thickness direction L thereof. The dielectric layer 11 may be made of at least one material selected from the group consisting of polyimide (PI), polyethylene terephthalate (PET), polyethylene naphthalate (PEN), polydimethylsiloxane (PDMS), liquid crystal polymer (LCP), modified polyimide (MPI), and the like.

In step S12, the copper layers 12a are processed to form inner circuit layers 12. Specifically, a resist film (not shown) may be laminated on a surface of each copper layer 12a facing away from the dielectric layer 11. And then the inner circuit layers 12 are formed through exposure, development, etching, resist stripping, and other steps. The steps of film lamination, exposure, development, etching, film stripping and the like are conventional technical means in the art and will not be repeated herein.

In step S13, the through groove 101 is formed in the dielectric layer 11 by laser drilling, mechanical drilling or the like, so as to obtain the inner substrate 10. The through groove 101 extends through the dielectric layer 11 along the thickness direction L of the dielectric layer 11 and is exposed from pattern gaps of the inner circuit layers 12.

Referring to FIG. 1, the inner substrate 10 includes the dielectric layer 11 and the inner circuit layers 12 formed on surfaces of the dielectric layer 11. In the embodiment, the inner circuit layers 12 are disposed on two opposite surfaces of the dielectric layer 11. The inner substrate 10 has the through groove 101 extending through the inner substrate 10 (the dielectric layer 11) along the thickness direction L thereof, and the through groove 101 is exposed from the pattern gaps of the inner circuit layers 12.

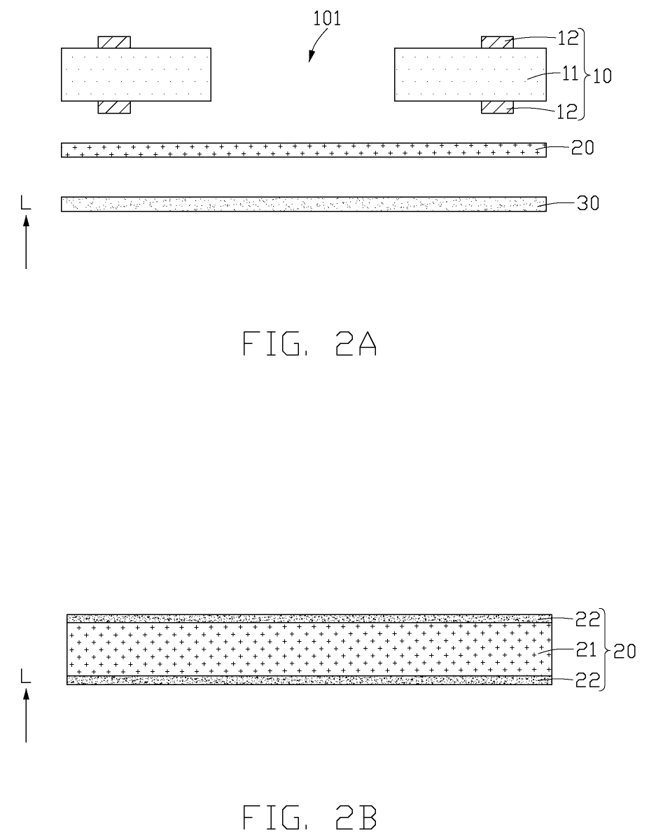

Referring to FIG. 2A, in step S20, a support layer 20 and a protection layer 30 are stacked on one side of the inner substrate 10. The support layer 20 is disposed between the inner substrate 10 and the protection layer 30. Referring to FIG. 2B, the support layer 20 includes a base layer 21 and adhesive layers 22 disposed on two opposite surfaces of the base layer 21. The protection layer 30 is configured to protect the support layer 20 from scratches. In addition, the protection layer 30 further provides a supporting function during a subsequent step of mounting a first electronic device 50 (referring to FIG. 4A), and can prevent contamination of a mounting position of a second electronic device 60 when the first electronic device 50 is mounted.

In some embodiments, the base layer 21 may be made of at least one material selected from the group consisting of polyimide, polyethylene terephthalate, polyethylene naphthalate, polydimethylsiloxane, liquid crystal polymer, and modified polyimide. In the embodiment, the base layer 21 is made of polyimide, and each adhesive layer 22 is made of Bonding Sheet (BS, epoxy-based pure adhesive).

In some embodiments, the protection layer 30 may be formed of, but is not limited to, polyethylene terephthalate (PET).

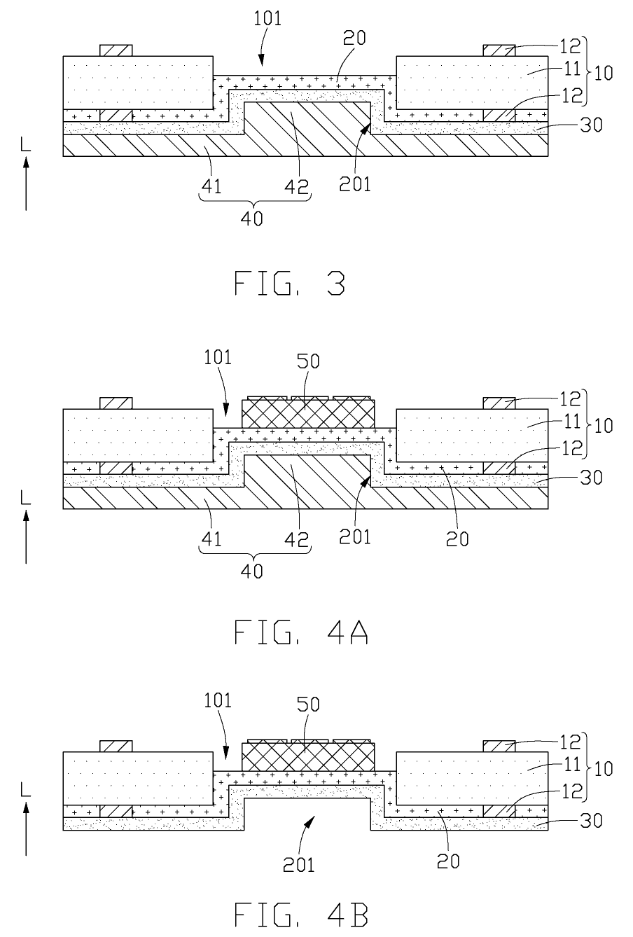

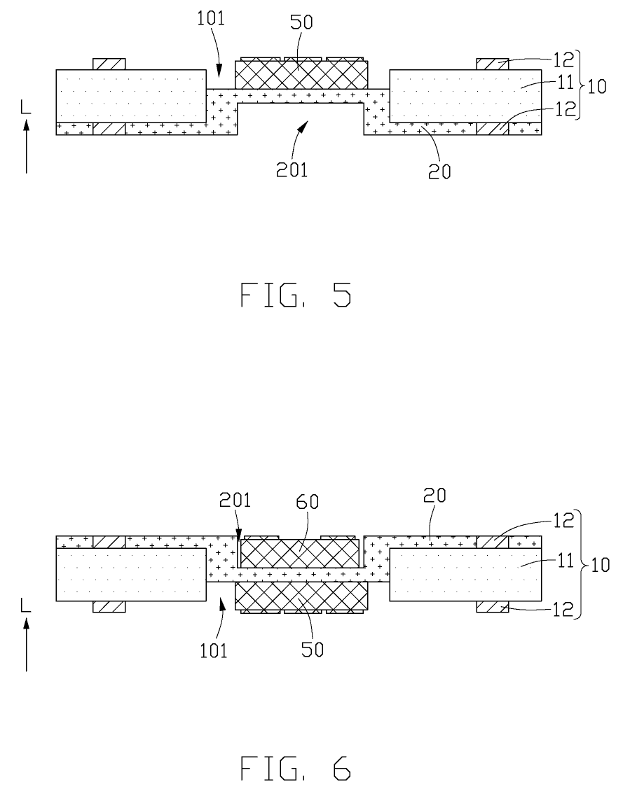

Referring to FIG. 3, in step S30, the support layer 20 and the protection layer 30 are laminated, such that portions of the support layer 20 and the protection layer 30 are attached to surfaces of the inner substrate 10, and portions of the support layer 20 and the protection layer 30 corresponding to the through groove 101 are recessed inside the through groove 101 to form a recess 201.

In some embodiments, referring to FIG. 3, a mold 40 may be used to mold the support layer 20 and the protection layer 30 by lamination. The mold 40 may include a body 41 and a protrusion 42 protruding from the body 41. The mold 40 is disposed on a side of the protection layer 30 facing away from the support layer 20, and the protrusion 42 is disposed corresponding to the through groove 101. During lamination, the protrusion 42 abuts against a portion of the protection layer 30 corresponding to the through groove 101, and other portions of the protection layer 30 are attached to the body 41. Pressure is then applied to the mold 40, and the protrusion 42 presses the protection layer 30 and the support layer 20, until the protection layer 30 and the support layer 20 are recessed inside the through groove 101 to form the recess 201. Portions of the protection layer 30 and the support layer 20 attached to the body 41 are fixed to surfaces of the inner substrate 10 via the adhesive layers 22, and the inner circuit layers 12 adjacent to the mold 40 are embedded in the support layer 20.

Referring to FIG. 3, in the embodiment, the protection layer 30 and the support layer 20 are only partially recessed inside the through groove 101. The support layer 20 does not seal an opening of the through groove 101 facing away from the mold 40, and a surface of the support layer 20 inside the through groove 101 facing away from the protection layer 30 is lower than a surface of the dielectric layer 11. That is, after lamination, a bottom wall of the through groove 101 is formed by the support layer 20. It can be understood that the depth of the recess 201 can be adjusted according to factors such as the thickness and weight of the first electronic device 50 (see FIG. 4A) to be mounted subsequently, the thickness of the base layer 21, and the like.

Further, the lamination pressure may between 2 kgf/cm² and 3 kgf/cm², the lamination time may between 30 seconds and 50 seconds, and the lamination temperature may between 120 degrees Celsius and 150 degrees Celsius. For example, the lamination pressure may be 3 kgf/cm², the lamination time may be 30 s, and the lamination temperature may be 120 degrees Celsius.

Referring to FIGS. 4A and 4B, in step S40, the first electronic device 50 is mounted inside the through groove 101. The first electronic device 50 is disposed on a surface of the support layer 20 facing away from the protection layer 30. Since the support layer 20 includes the adhesive layers 22, the first electronic device 50 can be fixed inside the through groove 101 via the adhesive layers 22. The mold 40 provides a certain supporting function when the first electronic device 50 is mounted. After fixation, the mold 40 is separated from the protection layer 30 and the inner substrate 10. In other embodiments, the mold 40 may be removed firstly, and then the first electronic device 50 may be mounted inside the through groove 101.

In some embodiments, referring to FIG. 4B, a gap may exist between the first electronic device 50 and the through groove 101. A surface of the first electronic device 50 facing away from the support layer 20 may be higher than a surface of the inner substrate 10 (the inner circuit layers 12), or may be flush with the surface of the inner substrate 10 (the inner circuit layers 12). The first electronic device 50 may include, but is not limited to, a chip.

Referring to FIG. 5, in step S50, the protection layer 30 is removed.

Referring to FIG. 6, in step S60, the second electronic device 60 is mounted inside the recess 201. The second electronic device 60 may include, but is not limited to, a chip. Since the support layer 20 includes the adhesive layers 22, the second electronic device 60 can be fixed inside the recess 201 via the adhesive layers 22. The size of the second electronic device 60 may be exactly matched with that of the recess 201, and the second electronic device 60 may be exactly received inside the recess 201. Alternatively, the second electronic device 60 may be slightly smaller than the recess 201, and a gap is formed between the second electronic device 60 and the recess 201. A surface of the second electronic device 60 facing away from the first electronic device 50 may be flush with a surface of the support layer 20 facing away from the dielectric layer 11.

In some embodiments, referring to FIG. 6, before mounting the second electronic device 60, the inner substrate 10 may be flipped so that the first electronic device 50 is disposed below the support layer 20 and the recess 201 is disposed above the first electronic device 50, thereby facilitating mounting of the second electronic device 60.

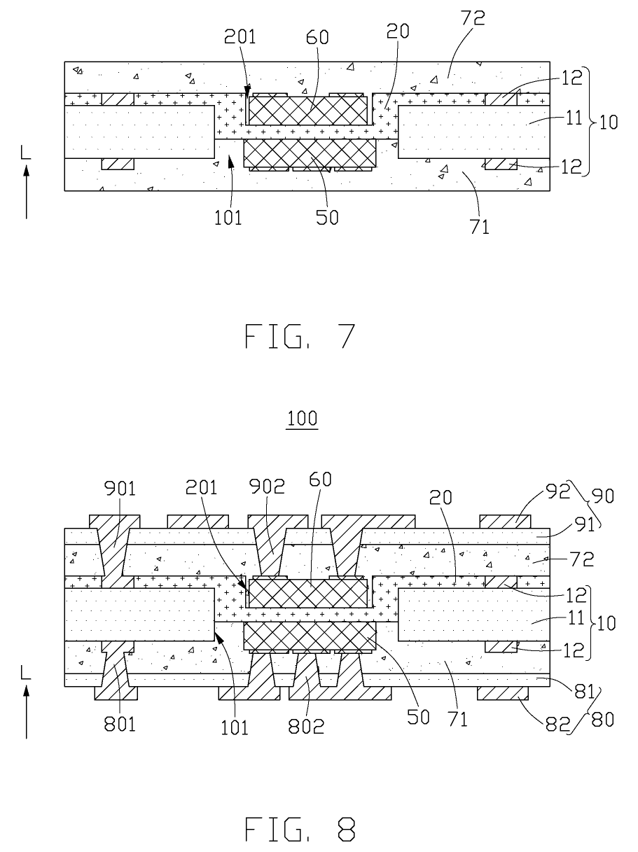

Referring to FIG. 7, in step S70, a first adhesive layer 71 is disposed on a surface of the inner substrate 10 facing away from the support layer 20, and a second adhesive layer 72 is disposed on a surface of the support layer 20 facing away from the inner substrate 10. The first adhesive layer 71 and the second adhesive layer 72 may be formed of conventional or non-conventional adhesives in the art, which is not limited in the present disclosure.

Referring to FIG. 7, the first adhesive layer 71 may cover surfaces of the inner circuit layers 12, the first electronic device 50, and the dielectric layer 11 exposed from the inner circuit layers 12, and fill a gap between the first electronic device 50 and the through groove 101. The second adhesive layer 72 may cover surfaces of the support layer 20, the second electronic device 60, and the inner circuit layers 12 exposed from the support layer 20, and fill a gap between the second electronic device 60 and the recess 201.

Referring to FIG. 8, in step S80, a first outer substrate 80 is laminated on a surface of the first adhesive layer 71 facing away from the inner substrate 10 (i.e., a surface of the inner substrate 10 facing away from the support layer 20), and a second outer substrate 90 is laminated on a surface of the second adhesive layer 72 facing away from the support layer 20 (i.e., a surface of the support layer 20 facing away from the inner substrate 10), so as to obtain the circuit board assembly 100.

In some embodiments, referring to FIG. 8, the first outer substrate 80 includes a first dielectric layer 81 and a first outer circuit layer 82 formed on a surface of the first dielectric layer 81. The first dielectric layer 81 is disposed between the first outer circuit layer 82 and the first adhesive layer 71. In the embodiment, the first outer substrate 80 is composed of one first dielectric layer 81 and one first outer circuit layer 82. In other embodiments, the first outer substrate 80 may include a plurality of first dielectric layers 81 and a plurality of first outer circuit layers 82, and one first dielectric layer 81 is disposed between every two adjacent first outer circuit layers 82.

Further, the first dielectric layer 81 may be made of at least one material selected from the group consisting of PI, PET, PEN, PDMS, LCP, MPI, and the like. The material of the first dielectric layer 81 may be the same as or different from that of the dielectric layer 11, which is not limited in the present disclosure. The first outer circuit layer 82 may include, but is not limited to, copper.

In some embodiments, referring to FIG. 8, the second outer substrate 90 includes a second dielectric layer 91 and a second outer circuit layer 92 formed on a surface of the second dielectric layer 91. The second dielectric layer 91 is disposed between the second outer circuit layer 92 and the second adhesive layer 72. In the embodiment, the second outer substrate 90 is composed of one second dielectric layer 91 and one second outer circuit layer 92. In other embodiments, the second outer substrate 90 may include a plurality of second dielectric layers 91 and a plurality of second outer circuit layers 92, and one second dielectric layer 91 is disposed between every two adjacent second outer circuit layers 92.

Further, the second dielectric layer 91 may be made of at least one material selected from the group consisting of PI, PET, PEN, PDMS, LCP, MPI, and the like. The material of the second dielectric layer 91 may be the same as or different from that of the dielectric layer 11, and may be the same as or different from that of the first dielectric layer 81, which is not limited in the present disclosure. The second outer circuit layer 92 may include, but is not limited to, copper.

In some embodiments, referring to FIG. 8, the circuit board assembly 100 further includes conductive structures 801, 802, 901, 902. The first outer substrate 80 may be electrically connected to the inner substrate 10 via the conductive structure 801, and may be electrically connected to the first electronic device 50 via the conductive structure 802. The second outer substrate 90 may be electrically connected to the inner substrate 10 via the conductive structure 901, and may be electrically connected to the second electronic device 60 via the conductive structure 902. The conductive structures 801, 802, 901, 902 may include, but are not limited to, conductive vias.

Referring to FIG. 8, the circuit board assembly 100 manufactured by the method is provided according to one embodiment of the present disclosure. The circuit board assembly 100 includes the inner substrate 10, the support layer 20, the first electronic device 50, the second electronic device 60, the first outer substrate 80, and the second outer substrate 90.

The inner substrate 10 is a circuit board formed with conductive circuits, and has the through groove 101 extending through the inner substrate 10 along the thickness direction L thereof. Specifically, the inner substrate 10 may include the dielectric layer 11 and the at least one inner circuit layer 12 formed on one surface or respective opposing surfaces of the dielectric layer 11. In the embodiment, the inner circuit layers 12 are disposed on two opposite surfaces of the dielectric layer 11. The through groove 101 extends through the dielectric layer 11 along the thickness direction L of the dielectric layer 11 and is exposed from the pattern gaps of the inner circuit layers 12.

The support layer 20 is disposed on one surface of the inner substrate 10, and a portion of the support layer 20 is recessed inside the through groove 101 to form the recess 201. The support layer 20 includes the base layer 21 and the adhesive layers 22 disposed on two opposite surfaces of the base layer 21.

The first electronic device 50 is mounted inside the through groove 101 and fixed to a surface of the support layer 20 facing away from the recess 201 via the adhesive layers 22. That is, the first electronic device 50 is embedded in the inner substrate 10. The first electronic device 50 may include, but is not limited to, a chip.

The second electronic device 60 is mounted inside the recess 201. That is, the second electronic device 60 is embedded in the inner substrate 10. Since the support layer 20 includes the adhesive layers 22, the second electronic device 60 can be fixed inside the recess 201 via the adhesive layers 22. The second electronic device 60 may include, but is not limited to, a chip.

The first outer substrate 80 is disposed on a surface of the inner substrate 10 facing away from the support layer 20, and the second outer substrate 90 is disposed on a surface of the support layer 20 facing away from the inner substrate 10.

In some embodiments, referring to FIG. 8, the circuit board assembly 100 further includes the first adhesive layer 71 and the second adhesive layer 72. The first adhesive layer 71 is disposed between the inner substrate 10 and the first outer substrate 80. The first adhesive layer 71 may cover surfaces of the inner circuit layers 12, the first electronic device 50, and the dielectric layer 11 exposed from the inner circuit layers 12, and fill the gap between the first electronic device 50 and the through groove 101. The second adhesive layer 72 is disposed between the support layer 20 and the second outer substrate 90. The second adhesive layer 72 may cover surfaces of the support layer 20, the second electronic device 60, and the inner circuit layers 12 exposed from the support layer 20, and fill the gap between the second electronic device 60 and the recess 201.

In some embodiments, referring to FIG. 8, the first outer substrate 80 includes the first dielectric layer 81 and the first outer circuit layer 82 formed on the surface of the first dielectric layer 81. The first dielectric layer 81 is disposed between the first outer circuit layer 82 and the first adhesive layer 71. In the embodiment, the first outer substrate 80 is composed of one first dielectric layer 81 and one first outer circuit layer 82. In other embodiments, the first outer substrate 80 may include a plurality of first dielectric layers 81 and a plurality of first outer circuit layers 82, and one first dielectric layer 81 is disposed between every two adjacent first outer circuit layers 82.

In some embodiments, referring to FIG. 8, the second outer substrate 90 includes the second dielectric layer 91 and the second outer circuit layer 92 formed on the surface of the second dielectric layer 91. The second dielectric layer 91 is disposed between the second outer circuit layer 92 and the second adhesive layer 72. In the embodiment, the second outer substrate 90 is composed of one second dielectric layer 91 and one second outer circuit layer 92. In other embodiments, the second outer substrate 90 may include a plurality of second dielectric layers 91 and a plurality of second outer circuit layers 92, and one second dielectric layer 91 is disposed between every two adjacent second outer circuit layers 92.

In some embodiments, referring to FIG. 8, the circuit board assembly 100 further includes the conductive structures 801, 802, 901, 902. The first outer substrate 80 may be electrically connected to the inner substrate 10 via the conductive structure 801, and may be electrically connected to the first electronic device 50 via the conductive structure 802. The second outer substrate 90 may be electrically connected to the inner substrate 10 via the conductive structure 901, and may be electrically connected to the second electronic device 60 via the conductive structure 902. The conductive structures 801, 802, 901, 902 may include, but are not limited to, conductive vias.

In the circuit board assembly 100 and the method thereof provided by the embodiments of the present disclosure, the support layer 20 (including the base layer 21 and the adhesive layers 22) is directly embedded in the through groove 101 of the inner substrate 10, and the support layer 20 is recessed inside the through groove 101 to form the recess 201, so that embedded electronic devices can be respectively disposed in the through groove 101 and the recess 201. The support layer 20 does not need to be peeled off, thereby simplifying the process, improving production efficiency, and avoiding the problem of adhesive layer residue during peeling. In addition, the electronic devices are respectively disposed on upper and lower surfaces of the inner substrate 10, that is, components can be mounted on both upper and lower sides of the inner substrate 10, thus improving the space utilization rate of the circuit board assembly 100.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A method for manufacturing a circuit board assembly with embedded electronic devices, comprising:
providing an inner substrate, the inner substrate defining a through groove extending through the inner substrate along a thickness direction of the inner substrate;
stacking a support layer and a protection layer on one side of the inner substrate, the support layer being disposed between the inner substrate and the protection layer, the support layer comprising a base layer and adhesive layers disposed on two opposite surfaces of the base layer;
laminating the support layer and the protection layer, such that portions of the support layer and the protection layer are recessed inside the through groove to form a recess;
mounting a first electronic device inside the through groove, the first electronic device being disposed on a surface of the support layer facing away from the protection layer;
removing the protection layer;
mounting a second electronic device inside the recess; and
laminating a first outer substrate on a surface of the inner substrate facing away from the support layer, and laminating a second outer substrate on a surface of the support layer facing away from the inner substrate.

2. The method of claim 1, wherein before laminating the first outer substrate and the second outer substrate, the method further comprises:
disposing a first adhesive layer on a surface of the inner substrate facing away from the support layer, and disposing a second adhesive layer on a surface of the support layer facing away from the inner substrate.

3. The method of claim 2, wherein the first adhesive layer fills a gap between the first electronic device and the through groove, and the second adhesive layer fills a gap between the second electronic device and the recess.

4. The method of claim 2, wherein the first outer substrate comprises at least one first dielectric layer and at least one first outer circuit layer formed on a side of the at least one first dielectric layer, and the first adhesive layer is disposed on another side of the at least one first dielectric layer.

5. The method of claim 2, wherein the second outer substrate comprises at least one second dielectric layer and at least one second outer circuit layer formed on a side of the at least one second dielectric layer, and the second adhesive layer is disposed on another side of the at least one second dielectric layer.

6. The method of claim 1, wherein laminating the support layer and the protection layer further comprises:
molding the support layer and the protection layer by lamination using a mold comprising a body and a protrusion protruding from the body, and molding the support layer and the protection layer by lamination using the mold comprising placing the protrusion of the mold corresponding to the through groove, and pressing the protrusion on portions of the support layer and the protection layer until the support layer and the protection layer are recessed inside the through groove to form the recess.

7. The method of claim 6, wherein molding the support layer and the protection layer by lamination using the mold further comprises controlling a lamination pressure between 2 kgf/cm² and 3 kgf/cm² controlling a lamination time 30 seconds between 50 seconds, and controlling a lamination temperature between 120 degrees Celsius and 150 degrees Celsius.

8. The method of claim 1, wherein a method for manufacturing the inner substrate comprises:
providing a copper clad laminate, the copper clad laminate comprising a dielectric layer and at least one copper layer disposed on one surface or respective opposing surfaces of the dielectric layer;
processing the copper layer to form at least one inner circuit layer; and
forming the through groove in the dielectric layer such that the through groove is exposed from a pattern gap of the at least one inner circuit layer.

9. The method of claim 1, wherein the base layer is made of at least one material selected from the group consisting of polyimide, polyethylene terephthalate, polyethylene naphthalate, polydimethylsiloxane, liquid crystal polymer, and modified polyimide.

10. The method of claim 1, wherein the protection layer comprises polyethylene terephthalate.

11. A circuit board assembly with embedded electronic devices, comprising:
an inner substrate having a through groove extending through the inner substrate along a thickness direction of the inner substrate;
a support layer disposed on one surface of the inner substrate, a portion of the support layer being recessed inside the through groove to form a recess, the support layer comprising a base layer and adhesive layers disposed on two opposite surfaces of the base layer;
a first electronic device mounted inside the through groove and disposed on a surface of each of the adhesive layers facing away from the recess;
a second electronic device mounted inside the recess;
a first outer substrate disposed on a surface of the inner substrate facing away from the support layer; and
a second outer substrate disposed on a surface of the support layer facing away from the inner substrate.

12. The circuit board assembly of claim 11, further comprising a first adhesive layer and a second adhesive layer; wherein the first adhesive layer is disposed between the inner substrate and the first outer substrate and filling a gap between the first electronic device and the through groove; and the second adhesive layer is disposed between the support layer and the second outer substrate and filling a gap between the second electronic device and the recess.

13. The circuit board assembly of claim 12, wherein the inner substrate comprises a dielectric layer and at least one inner circuit layer formed on one surface or respective opposing surfaces of the dielectric layer; the first outer substrate comprises at least one first dielectric layer and at least one first outer circuit layer formed on the at least one first dielectric layer, the at least one first dielectric layer is disposed between the at least one first outer circuit layer and the first adhesive layer.

14. The circuit board assembly of claim 12, wherein the second outer substrate comprises at least one second dielectric layer and at least one second outer circuit layer formed on the at least one second dielectric layer, the at least one second dielectric layer is disposed between the at least one second outer circuit layer and the second adhesive layer.

15. The circuit board assembly of claim 11, wherein the base layer is made of at least one material selected from the group consisting of polyimide, polyethylene terephthalate, polyethylene naphthalate, polydimethylsiloxane, liquid crystal polymer, and modified polyimide.

16. The circuit board assembly of claim 11, wherein the protection layer comprises polyethylene terephthalate.
